(19) United States
(12) Patent Application Publication
(10) Pub. No.: US 2007/0107880 A1
(43) Pub. Date: May 17, 2007

(54) Heat sink structure

(75) Inventors: Alex Hong, Kaohsiung City (TW); Miyahara Masaharu, Kaohsiung City (TW)

Correspondence Address: BACON & THOMAS, PLLC, 625 SLATERS LANE, FOURTH FLOOR, ALEXANDRIA, VA, 22314, US

(73) Assignee: Sunonwealth Electric Machine Industry Co., Ltd., Kaohsiung City (TW)

(21) Appl. No.: 11/280,175

(22) Filed: Nov. 17, 2005

(51) Int. Cl. H05K 7/20

(52) U.S. Cl. 165/104.33; 165/80.4; 361/697; 361/698

(57) ABSTRACT

The invention relates to a heat sink structure, which includes a central heat conducting body having a plurality of cooling fins extending from the periphery of the central heat conducting body, a through hole therein penetrating both sides thereof, and a cover plate and a bottom plate enclosing both openings of the through hole so as to form a chamber filled with a cooling liquid. The bottom plate is swappable with the material having a higher thermo-conductivity coefficient than that of the chamber so as to have faster and better heat absorption and heat transfer effect. If combined with the auxiliary cooling fins, the heat exchange area of the cooling liquid not only is increased, but also the mixing turbulent flow effect of the cooling liquid is enhanced so that the heat absorbed is more swiftly and uniformly diffused to provide the fastest and the most efficient cooling effect.

### FIELD OF THE INVENTION

The invention relates to a heat sink structure, which is disposed in CPU of electronic products to absorb and conduct the dissipated heat thereof.

### BACKGROUND OF THE INVENTION

As shown in FIG. 1, what Taiwan Patent Application No. 94130233 discloses is a heat sink device containing a cooling fan 50 and a heat sink 21. The heat sink 21 directly contacts with a heating element 81 to absorb the heat therefrom. The cooling fan 50 is disposed on the heat sink 21 to dissipate heat.

The heat sink 21 contains a central heat conducting body 22. A plurality of cooling fins 23 extend from the periphery of the central heat conducting body 22. The central heat conducting body 22 has an hole penetrating through one side, and the opening of the hole is sealed by a cover plate 24 so as to form an fully sealed hollow chamber 221. The chamber 221 is filled with a cooling liquid and disposed an agitator 25. The locations corresponding to the agitator 25 and a rotor of the cooling fan are disposed the permeability components 251 & 54 having the magnetic attraction and mutual traction therebetween so that the agitator 25 can synchronously rotate with the rotor 53.

As a result, when the agitator 25 synchronously rotate with the rotor 53, the cooling liquid filled in the chamber 221 is thus agitated such that the cooling liquid carrying heat becomes a dynamic hot liquid immediately and uniformly diffusing and conducting the heat to each cooling fin to facilitate the heat dissipation of the cooling fan 23.

Accordingly, the heat conduction speed of the heat sink 21 is critical to the heat transfer performance of the entire heat dissipation module. As the cooling liquid in the chamber 221 absorbs the heat of a heating element 81 in accordance with the heat transfer performance of the heat sink 21, when the heat transfer speed is low, there is no way for the agitator 25 to perform; the agitator can only outperform in terms of heat dissipation effect when the heat transfer speed is high. Based on the spirit striking for perfection, the present invention particularly targets at the heat transfer speed issue to further improve so as to attain faster and more efficient heat dissipation effect.

### SUMMARY OF THE INVENTION

In view of this, the invention thus provides a heat sink structure. The heat sink includes a central heat conducting body that has a plurality of cooling fins extending from the periphery of the central conducting body, through holes therein penetrating two side, and a cover plate and a bottom plate sealing the openings of the through holes, in formation of a hollow chamber. The chamber is filled with a cooling liquid and is disposed an agitator. The agitator and a rotor of a cooling fan are disposed permeability components thereon magnetically attracting and mutually dragging at the corresponding locations so that the agitator synchronously rotates with the rotor.

Because the bottom plate can be easily replaced with the material with higher thermo-conductivity coefficient, it can rapidly absorb the heat of the heating element and swiftly conduct the heat to the cooling liquid.

Together with the aid of the fin design, when the agitator agitates the cooling liquid, on the one hand those fins can increase the contact area of the fins and the cooling liquid, and on the other hand the turbulent flow mixing effect of the cooling liquid can be increased, so that the absorbed heat can be diffused in a fast and uniform way, providing an efficient heat dissipation effect.

### BRIEF DESCRIPTION OF THE DRAWINGS

FIG. 1 is a schematic view showing the cross-sectional view of the conventional structure;

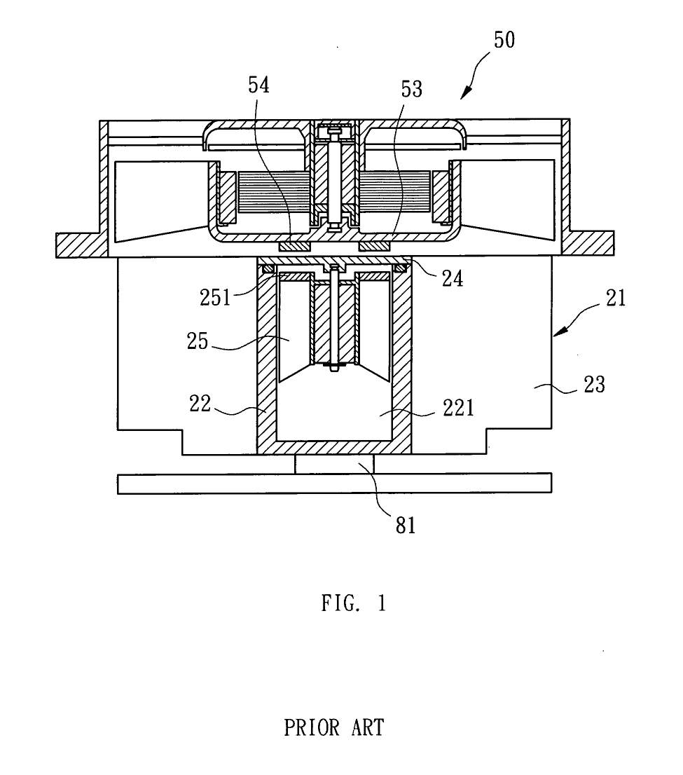

FIG. 2 is an exploded schematic view showing the first preferred embodiment of the present invention;

FIG. 3 is a cross-sectional view showing the first preferred embodiment of the present invention;

FIG. 4 is an exploded view showing the second schematic view of the present invention;

FIG. 5 is a cross-sectional schematic view showing the second preferred embodiment of the present invention;

FIG. 6 is a cross-sectional view showing the third preferred embodiment of the present invention; and

FIG. 7 is a cross-sectional view showing the fourth preferred embodiment of the present invention.

### DETAILED DESCRIPTION OF THE PREFERRED EMBODIMENT

The invention relates to a heat sink structure, wherein the central heat conducting body of the heat sink has through-holes penetrating two sides thereof, and the openings of both sides are covered with a cover plate and a bottom plate respectively so as to form an absolutely sealed hollow chamber. The bottom plate can be manufactured with the material with a higher thermo-conductivity coefficient so that the heat generated by the heating element can be swiftly absorbed to facilitate the heat dissipation of the cooling fan.

Here are some preferred embodiments as follows to illustrate the respective positions of the parts in the present invention.

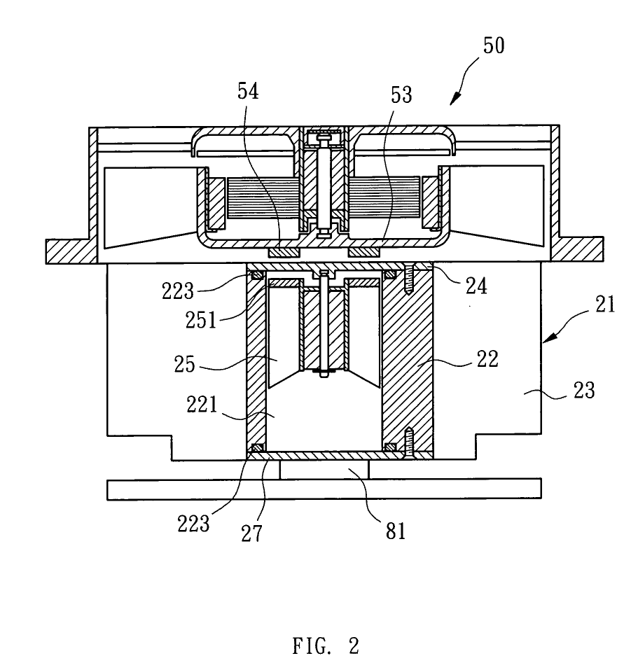

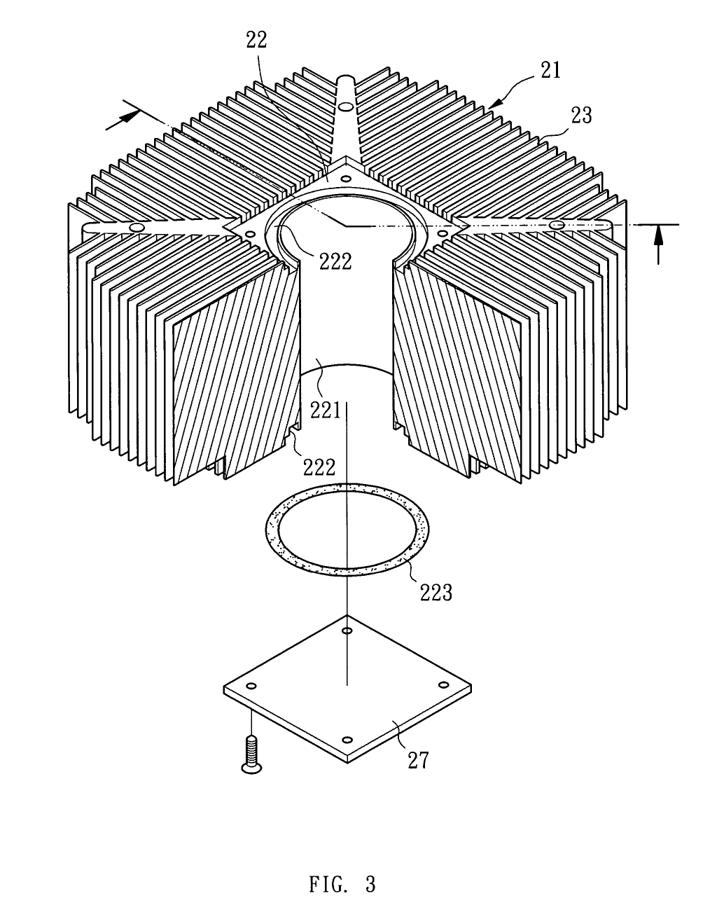

Please also refer to FIG. 2 and FIG. 3. The heat sink 21 has a central heat conducting body 22. A plurality of cooling fins 23 extend from the periphery of the central heat conducting body 22. The central heat conducting body 22 has a through hole, which penetrating two sides. The openings on the two sides are covered by a cover plate 24 and a bottom plate 27 respectively. The engagement means pertains to one fastened by screw (as shown in FIG. 3) or rivet, or by gluing capable of achieving the sealing effect.

The sides of the central heat conducting body 22 corresponding the cover plate 24 and the bottom plate 27 have an annular slot 222 filled with an O ring 223 so as to make the chamber 223 a fully sealed space.

The chamber 221 is filled with a cooling liquid and disposed an agitator 25. There is a cooling fan 50 on top of the heat sink 21. The permeability components 251, 54 where are disposed on the corresponding positions of the agitator 25 and the rotor 53 of the cooling fan 50 magnetically attract and mutually drag so that the agitator 25 synchronously rotates with the rotor 53.

The design of the invention allows the bottom plate 27 to be manufactured with the material easily swapped by those having thermo-conductivity coefficient higher than that of the heat sink 21, e.g. the material with high thermo-conductivity coefficient like copper, silver and so forth. When the bottom plate 27 is in contact with the heating element 81, it can absorb and conduct the heat generated by the heating element 81 more quickly and swiftly transfer the heat to be absorbed by the cooling liquid in the chamber 221.

As a consequence, while coupling with the agitator 25 to agitate the cooling liquid, the heat dissipation effect can be even more performed. The cooling liquid absorbing heat becomes a dynamic hot liquid and immediately and uniformly diffuse and conduct heat to each cooling fin to facilitate the heat dissipation of the cooling fan 50, attaining a faster and more efficient cooling effect.

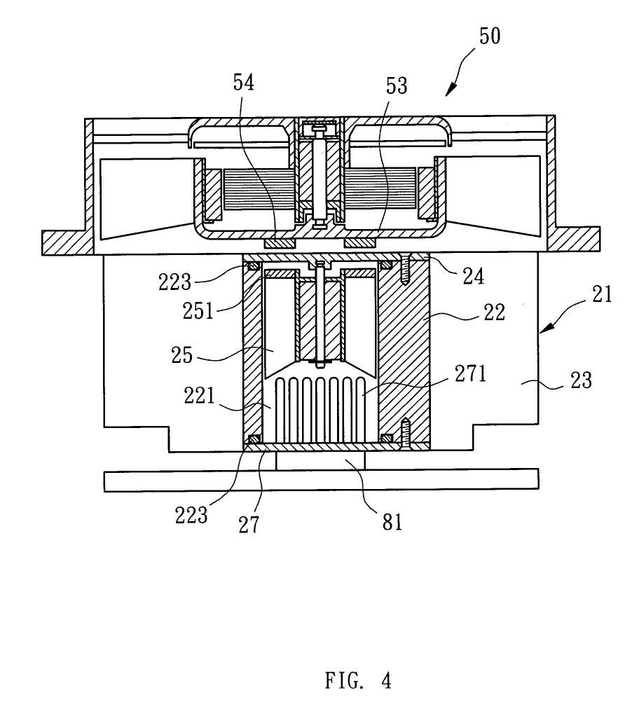

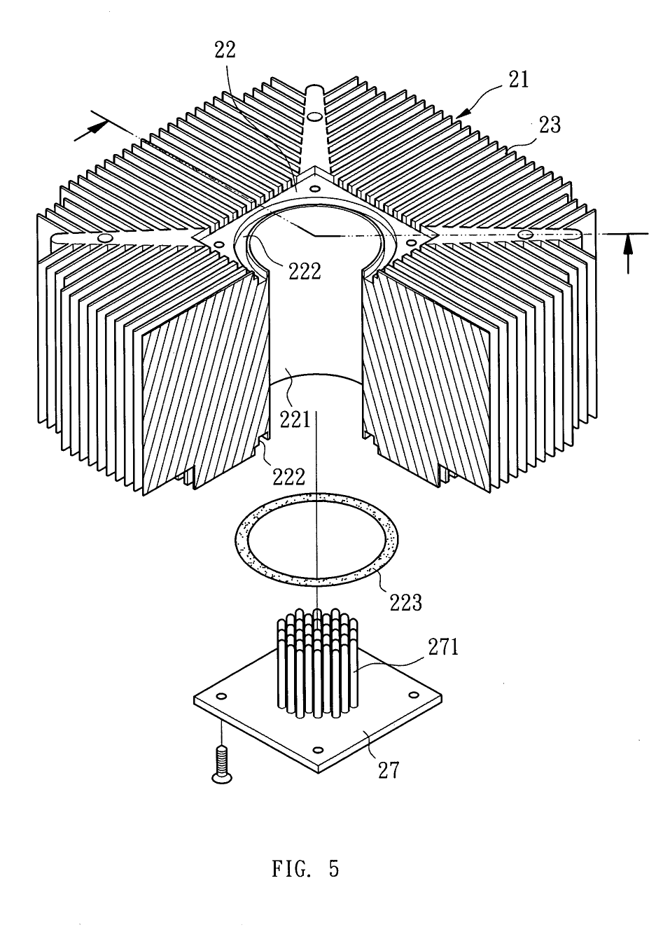

Besides, also as shown in FIG. 4 and FIG. 5, one side of the bottom plate 27 facing to the chamber 221 is disposed a plurality of auxiliary fins 271 additionally. These auxiliary fins 271 are a protrusion in form of a circular cylinder, a square cylinder or laminated shape (circular cylinder shown in FIG. 4 so as to conduct and diffuse the heat of large area to the cooling liquid more quickly.

Therefore, when the agitator 25 agitates the cooling liquid, on the one hand, these auxiliary fins 271 increase the contact area with the cooling liquid so as to augment the heat transfer efficiency, on the other hand, the agitated turbulent flow effect of the cooling liquid is enhanced such that the heat absorbed by the cooling liquid can be more swiftly and uniformly conducted to every cooling fin 23 to facilitate the heat dissipation of the cooling fan 50.

Furthermore, when the auxiliary cooling fins are designed with different heights, the cooling liquid collides with the auxiliary cooling fins with different heights. The resulting turbulent flows are all different so as to generate more turbulent flow in the chamber.

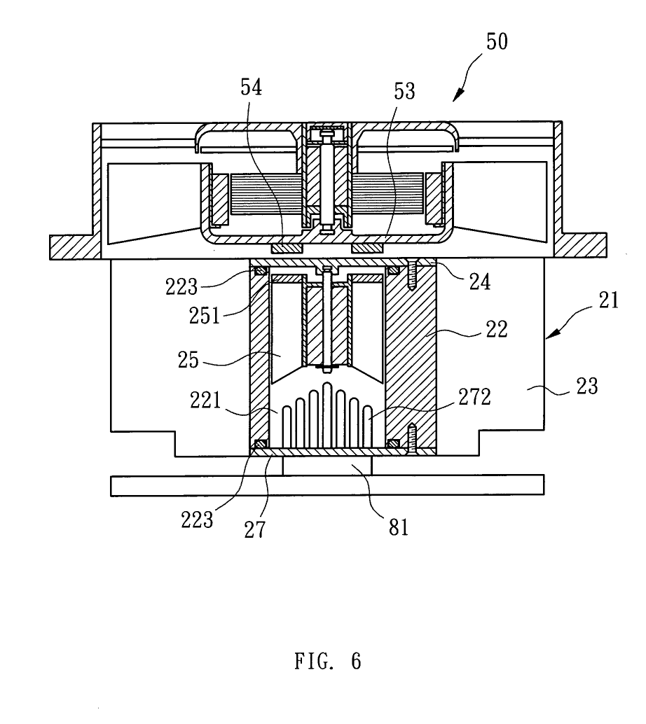

As shown in FIG. 6, the auxiliary cooling fins 272 on the bottom plate 27 are designed in a way having the top height at the center and the progressively decreased heights distributed along either direction from the center so that the cooling liquid collides the orderly distributed auxiliary cooling fins 272 to result in more turbulent flow in the chamber 221.

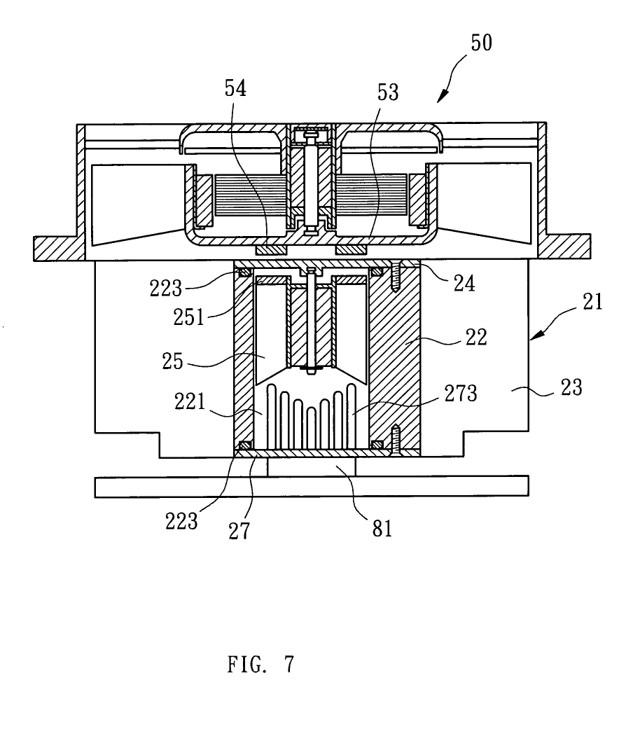

Also as shown in FIG. 7, the auxiliary cooling fins 272 are designed in a way having the top heights on both ends and the progressively decreased heights distributed from both ends to the center so that the cooling liquid forms the turbulent flow between any two of the auxiliary cooling fins so as to swiftly diffuse the heat absorbed by the cooling liquid, providing the optimal cooling effect.

In sum, the heat sink designed in the invention facilitates to replace the bottom plate with better heat transfer speed so as to provide better heat transfer and heat diffusion and rapidly carry away the heat generated by the heating element. If the design of the auxiliary fins are combined, on the one hand, the contact area of the cooling liquid are increased, on the other hand, the mixing effect of more turbulent flows are formed so that the heat absorbed by the cooling liquid can be more swiftly and uniformly transferred to every cooling fin. Therefore, the present invention not only has a novelty and a progressiveness, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the specification, appended claims or figures, which are to be accorded with the broadest interpretation so as to encompass all such modifications and similar structures.

What is claimed is:

1. A heat sink structure, comprising a central heat conducting body having a plurality of cooling fins extending from a periphery of said central heat conducting body, a through hole penetrating both sides therein, and a cover plate and a bottom plate enclosing both openings of said through hole respectively so as to form a chamber filled with a cooling liquid, wherein said bottom plate is swappable with a material having a thermo-conductivity coefficient higher than said thermo-conductivity coefficient of said heat sink.

2. The heat sink structure of claim 1, wherein a side of said bottom plate facing to said chamber has a plurality of auxiliary cooling fins.

3. The heat sink structure of claim 2, wherein said auxiliary cooling fins are a plurality of projections having a form selected from one group of a cylinder, a square cylinder and a lamination.

4. The heat sink structure of claim 2, wherein said auxiliary cooling fins are designed with different heights.

5. The heat sink structure of claim 4, wherein said auxiliary cooling fins have a top height at a center and a plurality of heights progressively decreasing from said center.

6. The heat sink structure of claim 4, wherein said auxiliary cooling fins have a top height on a perimeter of said heat sink structure and a plurality of heights progressively decreasing from said perimeter to said center.

7. The heat sink structure of claim 1, wherein an end face of said heat conducting body corresponding said bottom plate has an annular slot filled with an O-ring.

8. The heat sink structure of claim 1, wherein said chamber is disposed an agitator therein spinning and agitating said cooling liquid.
